(19) United States
(12) Patent Application Publication
(10) Pub. No.: US 2012/0249150 A1
(43) Pub. Date: Oct. 4, 2012

(54) SWITCH STATUS DETECTION CIRCUIT FOR MULTIPLE LIGHT LEVEL LIGHTING SYSTEMS

(75) Inventor: Viatcheslav Anissimov, Lynn, MA (US)

(73) Assignee: OSRAM SYLVANIA INC., Danvers, MA (US)

(21) Appl. No.: 13/077,151

(22) Filed: Mar. 31, 2011

(51) Int. Cl. G01R 31/02; H05B 37/02

(52) U.S. Cl. 324/415; 315/240

(57) ABSTRACT

A switch status detection circuit is provided, including three input terminals and a ground terminal. Two input terminals connect to a power supply via respective switches, receiving a respective voltage signal. The third connects to the power supply, receiving a neutral signal. A neutral synchronization circuit, between the third and the ground terminal, generates a positive pulsed current signal as a function of the neutral signal. Two capacitors, each with a respective first terminal connected to a corresponding input terminal, and a respective second terminal connected to the ground terminal, are charged by the current signal when the capacitor's corresponding switch is in an off state. Respective output terminals are coupled to each capacitor's first terminal to provide respective control signals, indicating the respective switch's state as a function of a voltage level across that capacitor. Each control signal has a logic level corresponding to its respective switch's state.

### TECHNICAL FIELD

The present invention relates to lighting, and more specifically, to lighting systems having multiple levels of light output controlled by two power line switches status of which is detected in order to obtain multiple light levels.

### BACKGROUND

Multiple level lighting systems, such as two or more level lighting systems, are used in various different lighting applications. For example, two level lighting systems are commonly used in overhead lighting. Such lighting systems can be used to conserve energy since they allow a portion of the lighting to be turned off when full light is not necessary. The lighting systems may be used to operate a variety of lamps, such as but not limited to gas discharge lamps, light emitting diode (LED) lamps, and other types of lamps.

A typical implementation of a two level lighting system includes two power switches and two power converters, wherein each power switch in the lighting system generates a control signal to control only one of the power converters in the lighting system. Turning on both of the switches at the same time powers both power converters, thus producing full light output from the lighting system. Turning on only one of the switches applies power to only one of the power converters in the lighting system and thus results in a reduced light level and a corresponding reduction in power consumed.

### SUMMARY

Conventional lighting systems, such as those described above, and other systems that operate using a plurality of control signals to control multiple power converters, are not as economical as a system including only a single power converter. For compatibility purposes, the power converter would be required to operate from the same two power switches used in the two power converter system. When both switches are closed, the power converter would operate in a first mode (e.g., a full light mode). Conversely, when only one of the two power switches is closed, the power converter would operate in a second mode (e.g., a reduced light mode).

Embodiments of the present invention provide a switch status detection circuit that provides multiple control signals for use with a system, such as but not limited to a multiple level lighting system, that uses only a single power converter. In particular, embodiments are directed to a power converter having a first switch and a second switch for selectively connecting the power converter, respectively, to a first power line and to a second power line. The power converter includes a converter circuit that provides power (i.e., current, voltage) to operate one or more loads connected thereto, and a switch status detection circuit that controls the converter circuit based on the states of the first and second switches. The switch status detection circuit is self-powered via the first power line and the second power line.

In an embodiment, there is provided a switch status detection circuit. The switch status detection circuit includes: a first input terminal adapted to connect to an AC power supply via a first switch and to receive a first voltage signal with respect to ground potential from the AC power supply; a second input terminal adapted to connect to the AC power supply via a second switch and to receive a second voltage signal with respect to ground potential from the AC power supply; a third input terminal adapted to connect to a neutral input terminal of the AC power supply and to receive a neutral voltage signal with respect to ground potential from the AC voltage supply; a ground terminal adapted to couple to ground potential; a neutral synchronization circuit connected between the third input terminal and the ground terminal, the neutral synchronization circuit configured to generate a positive pulsed current signal as a function of the neutral voltage signal; a first capacitor having a first terminal and a second terminal, wherein the first terminal of the first capacitor is coupled to the first input terminal, and wherein the second terminal of the first capacitor is coupled to the ground terminal, and wherein the positive pulsed current signal charges the first capacitor when the first switch is in an off state; a second capacitor having a first terminal and a second terminal, wherein the first terminal of the second capacitor is coupled to the second input terminal, and wherein the second terminal of the second capacitor is coupled to the ground terminal, and wherein the positive pulsed current signal charges the second capacitor when the second switch is in an off state; a first output terminal coupled to the first terminal of the first capacitor to provide a first control signal that indicates a state of the first switch as a function of a voltage level across the first capacitor, the first control signal having a first logic level when the first switch is in the off state, the first control signal having a second logic level when the when the first switch is in an on state; and a second output terminal coupled to the first terminal of the second capacitor to provide a second control signal that indicates a state of the second switch as a function of a voltage level across the second capacitor, the second control signal having a first logic level when the second switch is in the off state, the second control signal having a second logic level when the when the second switch is in an on state.

In a related embodiment, the neutral synchronization circuit may include: a resistor connected to the third input terminal; a neutral synchronization capacitor connected in series with the resistor; and a diode having an anode connected to the ground terminal, and a cathode connected to the neutral synchronization capacitor. In a further related embodiment, the switch status detection circuit may further include: a first transistor having a base terminal, an emitter terminal, and a collector terminal, wherein the base terminal of the first transistor is connected to the neutral synchronization capacitor, the emitter terminal of the first transistor is connected to the first input terminal via a first detection channel diode, and the collector terminal of the first transistor is connected to the emitter terminal of the first transistor via a first detection channel resistor; and a second transistor having a base terminal, an emitter terminal, and a collector terminal, wherein the base terminal of the second transistor is connected to the neutral synchronization capacitor, the emitter terminal of the second transistor is connected to the second input terminal via a second detection channel diode, and the collector terminal of the second transistor is connected to the emitter terminal of the second transistor via a second detection channel resistor. In another further related embodiment, the switch status detector circuit may further include: a first inverter stage to generate the first control signal as a function of the voltage level across the first capacitor; and a second inverter stage to generate the second control signal as a function of the voltage level across the second capacitor.

In another related embodiment, the first control signal may have a low logic level when the first switch is in the off state and the first control signal may have a high logic level when the first switch is in the on state, and the second control signal may have a low logic level when the second switch is in the off state and the second control signal may have a high logic level when the second switch is in the on state. In still another related embodiment, the first output terminal may be connected to a lighting system converter circuit to provide the first control signal thereto, and the second output terminal may be connected to the lighting system converter circuit to provide the second control signal thereto, wherein the lighting system converter circuit may provide voltage to a plurality of lamps as a function of the logic level of the first control signal and the logic level of the second control signal.

In another embodiment, there is provided a method implemented by a switch status detection circuit. The method includes: receiving a first voltage signal from an alternating current (AC) power supply via a first input terminal relative to ground potential, wherein the first input terminal is connected to the AC power supply via a first switch, and wherein the first voltage signal has a phase corresponding to the state of the first switch; receiving a second voltage signal from an AC power supply via a second input terminal relative to ground potential, wherein the second input terminal is connected to the AC power supply via a second switch, and wherein the second voltage signal has a phase corresponding to the state of the second switch; receiving a neutral voltage signal from the AC power supply via a neutral input terminal relative to ground potential, wherein the neutral voltage signal has a phase; generating a first direct current (DC) voltage across a first capacitor as a function of the neutral voltage signal being in-phase with the first voltage signal; generating a second DC voltage across a second capacitor as a function of the neutral voltage signal being in-phase with the second voltage signal; generating a first control signal as a function of the DC voltage across the first capacitor, wherein the first control signal has a logic level corresponding to the DC voltage across the first capacitor; generating a second control signal as a function of the DC voltage across the second capacitor, wherein the second control signal has a logic level corresponding to the DC voltage across the second capacitor; and providing the first control signal and the second control signal to an output system, wherein the output system uses the first control signal and the second control signal to operate.

In a related embodiment, receiving a first voltage signal may include: receiving a first voltage signal from an alternating current (AC) power supply via a first input terminal relative to ground potential, wherein the first input terminal is connected to the AC power supply via a first switch, and wherein the first voltage signal has a first phase when the first switch is non-conductive, and the first voltage signal has a second phase when the first switch is conductive. In a further related embodiment, receiving a first voltage signal may include: receiving a first voltage signal from an alternating current (AC) power supply via a first input terminal relative to ground potential, wherein the first input terminal is connected to the AC power supply via a first switch, and wherein the first voltage signal has a first phase when the first switch is non-conductive, and the first voltage signal has a second phase when the first switch is conductive, wherein the second phase differs from the first phase by one hundred and eighty degrees. In yet another further related embodiment, receiving a second voltage signal may include: receiving a second voltage signal from an AC power supply via a second input terminal relative to ground potential, wherein the second input terminal is connected to the AC power supply via a second switch, and wherein the second voltage signal has a first phase when the second switch is non-conductive, and the second voltage signal has a second phase when the second switch is conductive. In a further related embodiment, receiving a second voltage signal may include: receiving a second voltage signal from an AC power supply via a second input terminal relative to ground potential, wherein the second input terminal is connected to the AC power supply via a second switch, and wherein the second voltage signal has a first phase when the second switch is non-conductive, and the second voltage signal has a second phase when the second switch is conductive, wherein the second phase differs from the first phase by one hundred and eighty degrees. In another further related embodiment, receiving a neutral voltage signal may include: receiving a neutral voltage signal from the AC power supply via a neutral input terminal relative to ground potential, wherein the neutral voltage signal is in-phase with the first voltage signal having the first phase and with the second voltage signal having the first phase.

In another related embodiment, generating a first control signal may include: generating a first control signal as a function of the DC voltage across the first capacitor, wherein the first control signal has a first logic level when the first DC voltage exists across the first capacitor and otherwise has a second logic level. In a further related embodiment, generating a second control signal may include: generating a second control signal as a function of the DC voltage across the second capacitor, wherein the second control signal has a first logic level when the second DC voltage exists across the second capacitor and otherwise has a second logic level. In a further related embodiment, generating a first control signal may include: generating a first control signal as a function of the DC voltage across the first capacitor, wherein the first control signal has a low logic level when the first switch is in a non-conductive state, and wherein the first control signal has a high logic level when the first switch is in a conductive state; and generating a second control signal may include: generating a second control signal as a function of the DC voltage across the second capacitor, wherein the second control signal has a low logic level when the second switch is in a non-conductive state, and wherein the second control signal has a high logic level when the second switch is in a conductive state.

In still another related embodiment, providing the first control signal and the second control signal to an output system may include: providing the first control signal and the second control signal to lighting system converter circuit, wherein the lighting system converter circuit uses the first control signal and the second control signal to control a lighting level of a plurality of lamps.

In another embodiment, there is provided a power converter to power a plurality of lamps from an alternating current (AC) power supply. The power converter includes: a first switch adapted to selectively connect the power converter to a first high voltage terminal of the AC power supply, the first switch having an on state and an off state; a second switch adapted to selectively connect the power converter to a second high voltage terminal of the AC power supply, the second switch having an on state and an off state; a lighting system converter circuit to provide power suitable for energizing at least one lamp in the plurality of lamps; and a switch status detection circuit including: a first input terminal coupled to the first switch to receive a first voltage signal with respect to ground potential from the AC power supply; a second input terminal coupled to the second switch to receive a second voltage signal with respect to ground potential from the AC power supply; a third input terminal coupled to a neutral input terminal of the AC power supply to receive a neutral voltage signal with respect to ground potential from the AC voltage supply; a ground terminal coupled to ground potential; a neutral synchronization circuit connected between the third input terminal and the ground terminal, the neutral synchronization circuit configured to generate a positive pulsed current signal as a function of the neutral voltage signal; a first capacitor having a first terminal and a second terminal, wherein the first terminal of the first capacitor is coupled to the first input terminal of the switch status detection circuit, and wherein the second terminal of the first capacitor is coupled to the ground terminal of the switch status detection circuit, and wherein the positive pulsed current signal charges the first capacitor when the first switch is in the off state; a second capacitor having a first terminal and a second terminal, wherein the first terminal of the second capacitor is coupled to the second input terminal of the switch status detection circuit, and wherein the second terminal of the second capacitor is coupled to the ground terminal of the switch status detection circuit, and wherein the positive pulsed current signal charges the second capacitor when the second switch is in the off state; a first output terminal coupled to the first terminal of the first capacitor and to the lighting system converter circuit to provide a first control signal to the lighting system converter circuit, wherein the first control signal indicates the state of the first switch as a function of a voltage level across the first capacitor, the first control signal having a first logic level when the first switch is in the off state, the first control signal having a second logic level when the when the first switch is in the on state; and a second output terminal coupled to the first terminal of the second capacitor and to the lighting system converter circuit to provide a second control signal to the lighting system converter circuit, wherein the second control signal indicates the state of the second switch as a function of a voltage level across the second capacitor, the second control signal having a first logic level when the second switch is in the off state, the second control signal having a second logic level when the when the second switch is in the on state; wherein the lighting system converter circuit receives the first control signal via the first output terminal of the switch status detection circuit and receives the second control signal via the second output terminal of the switch status detection circuit, and provides power to the plurality of lamps as a function of the logic level of the first control signal and the logic level of the second control signal.

In a related embodiment, the neutral synchronization circuit may include: a resistor connected to the third input terminal; a neutral synchronization capacitor connected in series with the resistor; and a diode having an anode connected to the ground terminal, and a cathode connected to the neutral synchronization capacitor. In a further related embodiment, the power converter may include: a first transistor having a base terminal, an emitter terminal, and a collector terminal, wherein the base terminal of the first transistor is connected to the neutral synchronization capacitor, the emitter terminal of the first transistor is connected to the first input terminal via a first detection channel diode, and the collector terminal of the first transistor is connected to the emitter terminal of the first transistor via a first detection channel resistor; and a second transistor having a base terminal, an emitter terminal, and a collector terminal, wherein the base terminal of the second transistor is connected to the neutral synchronization capacitor, the emitter terminal of the second transistor is connected to the second input terminal via a second detection channel diode, and the collector terminal of the second transistor is connected to the emitter terminal of the second transistor via a second detection channel resistor. In another further related embodiment, the power converter may further include: a first inverter stage to generate the first control signal as a function of the voltage level across the first capacitor; and a second inverter stage to generate the second control signal as a function of the voltage level across the second capacitor.

### BRIEF DESCRIPTION OF THE DRAWINGS

The foregoing and other objects, features and advantages disclosed herein will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles disclosed herein.

FIG. 1 is a schematic diagram, partially in block form, of a lamp system according to embodiments disclosed herein.

FIG. 2A illustrates a voltage signal measured with respect to neutral at a first terminal of a switch status detection circuit according to embodiments disclosed herein.

FIG. 2B illustrates a first control signal generated at a first output terminal of a switch status detection circuit according to embodiments disclosed herein.

FIG. 3A illustrates a voltage signal measured with respect to neutral at a second terminal of a switch status detection circuit according to embodiments disclosed herein.

FIG. 3B illustrates a first control signal generated at a second output terminal of a switch status detection circuit according to embodiments disclosed herein.

FIG. 4A illustrates a waveform representative of a voltage signal at a first terminal of a switch status detection circuit according to embodiments disclosed herein.

FIG. 4B illustrates a waveform representative of a voltage signal at a neutral terminal of a switch status detection circuit according to embodiments disclosed herein.

FIG. 4C illustrates a waveform representative of a current signal at a base terminal of a transistor of the first detection channel according to embodiments disclosed herein.

FIG. 4D illustrates a waveform representative of a current signal at a collector terminal of a transistor of the first detection channel according to embodiments disclosed herein.

FIG. 4E illustrates a waveform representative of a current signal at an emitter terminal of a transistor of the first detection channel according to embodiments disclosed herein.

FIG. 4F illustrates a waveform representative of a voltage signal measured across a capacitor of the first detection channel according to embodiments disclosed herein.

FIG. 5A illustrates a waveform representative of a voltage signal at a second terminal of a switch status detection circuit according to embodiments disclosed herein.

FIG. 5B illustrates a waveform representative of a voltage signal at a neutral terminal of a switch status detection circuit according to embodiments disclosed herein.

FIG. 5C illustrates a waveform representative of a current signal at a base terminal of a transistor of the second detection channel according to embodiments disclosed herein.

FIG. 5D illustrates a waveform representative of a current signal at a collector terminal of a transistor of the second detection channel according to embodiments disclosed herein.

FIG. 5E illustrates a waveform representative of a current signal at an emitter terminal of a transistor of the second detection channel according to embodiments disclosed herein.

FIG. 5F illustrates a waveform representative of a voltage signal measured across a capacitor of the second detection channel according to embodiments disclosed herein.

FIGS. 6, 7A-7B, 8A-8B, and 9 are block diagrams illustrating methods performed by a switch status detection circuit according to embodiments disclosed herein.

### DETAILED DESCRIPTION

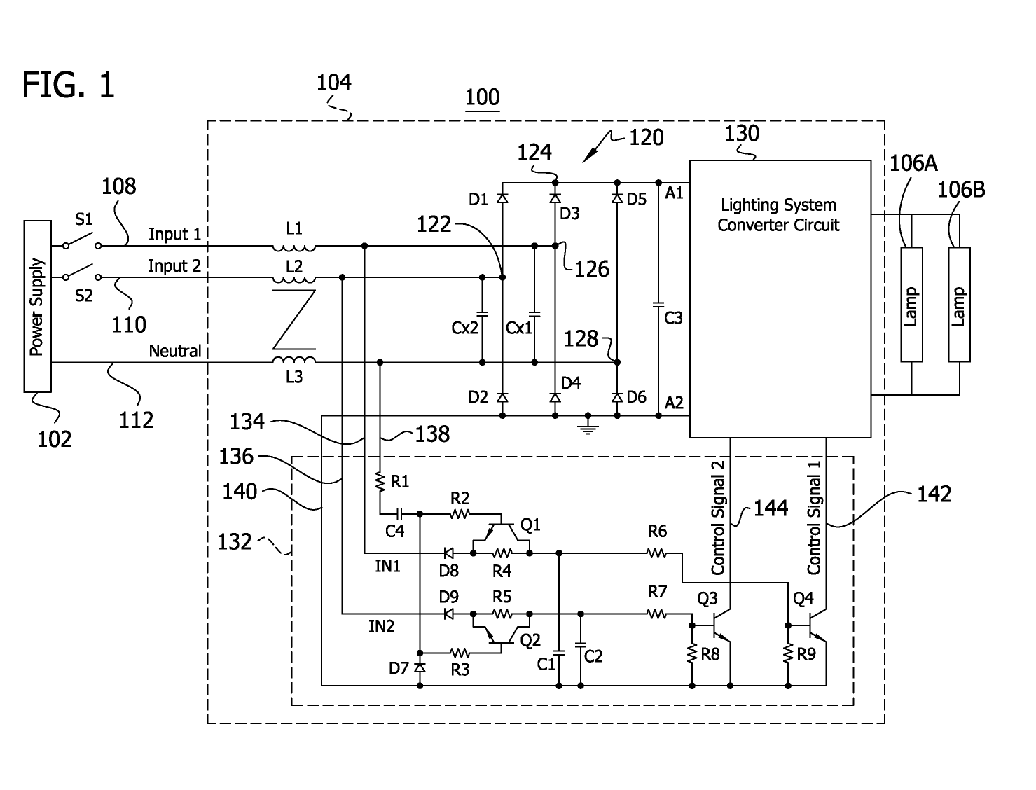

FIG. 1 illustrates a lamp system 100 including a switch status detection circuit 132. Though embodiments of the switch status detection circuit 132 are described herein with reference to a particular application (i.e., lighting) and a particular output system (i.e., the lamp system 100), the switch status detection circuit 132 may be used in any number of output systems without departing from the scope of the invention.

In addition to the switch status detection circuit 132, the lamp system 100 includes an input power source, such as but not limited to an alternating current (AC) power supply 102, a power converter 104, and a plurality of lamps 106A, 106B. The lamps may be connected together in parallel or in series. Although FIG. 1 shows the plurality of lamps 106A, 106B as including only two lamps 106A and 106B, connected together in parallel, the lamp system 100 may include any number of lamps connected together in parallel or in series. In some embodiments, one or more of the plurality of lamps 106A, 106B is an electrodeless gas discharge lamp, such as but not limited to the ICETRON® lamp available from OSRAM SYLVANIA, the QL® induction lamp available from Philips, the GENURA® lamp available from General Electric, and the EVERLIGHT® lamp available from Matsushita. In some embodiments, one or more of the plurality of lamps 106A, 106B is a solid state light source-based lamp, such as but not limited to a light emitting diode (LED) and/or organic light emitting diode (OLED) lamp. Thus, the lamp system 100 may be, and in some embodiments, is, used to energize other types of lamps not specifically mentioned herein without departing from the scope of the invention.

The power converter 104 includes a first high voltage input terminal 108 (i.e., line voltage input terminal, hot input terminal) to connect to a first high voltage terminal (e.g., hot wire) to the AC power supply 102, (e.g., standard 120V or 240V AC household power), and a second high voltage input terminal 110 (i.e., line voltage input terminal) to connect to a second high voltage terminal of the AC power supply 102. The power converter 104 also includes a neutral input terminal 112 to connect to a neutral wire of the AC power supply 102, and a ground terminal (not shown) connectable to ground potential. A first switch 51 is connected to the first high voltage input terminal 108. Accordingly, the first switch 51 is adapted to selectively connect the power converter 104 to the first high voltage terminal of the AC power supply 102. A second switch S2 is connected to the second high voltage input terminal 110. As such, the second switch S2 is adapted to selectively connect the power converter 104 to the second high voltage terminal of the AC power supply 102. The first switch 51 and the second switch S2 may be implemented by, for example but not limited to, conventional wall switches having at least one state, such as but not limited to an on state and an off state.

A rectifier circuit 120 is coupled to the first high voltage input terminal 108, the second high voltage input terminal 110, and the neutral terminal 112. In particular, the rectifier circuit 120 is coupled to the first high voltage input terminal 108 via a first electromagnetic interference (EMI) inductor L1. The rectifier circuit 120 is coupled to the second high voltage input terminal 110 via a second EMI inductor L2. The rectifier circuit 120 is coupled to the neutral terminal 112 via a third EMI inductor L3. As shown in FIG. 1, the rectifier circuit 120 is a full-wave rectifier implemented by an arrangement comprising a first diode D1, a second diode D2, a third diode D3, a fourth diode D4, a fifth diode D5, and a sixth diode D6. The first diode D1 has an anode coupled to a first node 122 and a cathode coupled to a second node 124. The first node 122 is coupled to the second high voltage input terminal 110 via the second EMI inductor L2. The second diode D2 has an anode coupled to ground potential and a cathode coupled to the first node 122. The third diode D3 has an anode coupled to a third node 126 and a cathode coupled to the second node 124. The third node 126 is coupled to first high voltage input terminal 108 via the first EMI inductor L1. The fourth diode D4 has an anode coupled to the ground potential and a cathode coupled to the third node 126. The fifth diode D5 has an anode coupled to a fourth node 128 and a cathode coupled to the second node 124. The fourth node 128 is coupled to the neutral input terminal 112 via the third EMI inductor L3. The sixth diode D6 has an anode coupled to ground potential and a cathode coupled to the fourth node 128.

A first EMI capacitor Cx1 is connected between the first high voltage input terminal 108 and the neutral terminal 112. A second EMI capacitor Cx2 is connected between the second high voltage input terminal 110 and the neutral terminal 112. Specifically, the first EMI capacitor Cx1 is connected between the third node 126 and the fourth node 128. The second EMI capacitor Cx2 is connected between the first node 122 and the fourth node 128. As shown in FIG. 1, a high frequency bypass capacitor C3 may be connected between the fourth node 128 and the ground potential.

In operation, the power converter 104 selectively receives a sinusoidal AC voltage signal from the AC power supply 102 via the first switch S1 and/or the second switch S2. The first EMI inductor L1, the second EMI inductor L2, the third EMI inductor L3, the first EMI capacitor Cx1 and the second EMI capacitor Cx2 reduce high frequency noise generated by the power converter 104. The rectifier circuit 120 receives the AC voltage signal and generates a rectified voltage signal therefrom. The high frequency bypass capacitor C3 reduces high frequency noise in the rectified voltage signal.

A lighting system converter circuit 130 is coupled to the rectifier circuit 120 via the high frequency bypass capacitor C3. The lighting system converter circuit 130 receives the rectified voltage signal and provides a voltage and current (i.e., power) suitable to energize the lamp 106. In some embodiments, the lighting system converter circuit 130 may include a power factor correction circuit (not shown) and/or an inverter circuit (not shown).

As stated above, the lamp system 100, and more particularly the power converter 104, includes the switch status detection circuit 132 to provide control signals to the lighting system converter circuit 130 as a function of states of the first switch Si and the second switch S2. The output stages Q3, Q4 of the switch status detection circuit 132 are configured as an “open collector output” circuit, providing control signals 142, 144. In some embodiments, they have pull-up resistors (not shown) inside the converter circuit 130 connected to a Vcc bias voltage of, for example but not limited to 10 VDC. In some embodiments, the first control signal 142 (i.e., control signal 1) is a voltage signal having a magnitude (e.g., voltage level) that is dependent on a state of the first switch S1. The second control signal 144 (i.e., control signal 2) is a voltage signal having a magnitude (e.g., voltage level) that is dependent on the state of the second switch S2. In turn, the lighting system converter circuit 130 provides a voltage signal to the plurality of lamps 106A, 106B as a function of the control signals received from the switch status detection circuit 132. The plurality of lamps 106A, 106B generate a particular amount of light (e.g., lumens, lighting level) as a function of the voltage signal (e.g., voltage level, voltage magnitude) provided to the plurality of lamps 106A, 106B by the switch status detection circuit 132 via the lighting system converter circuit 130.

As shown in FIG. 1, when the first switch S1 is in an off state, the magnitude of the first control signal provided by the switch status detection circuit 132 is at a first level (e.g., low level, 0 volts). When the first switch Si is in an on state, the magnitude of the first control signal provided by the switch status detection circuit 132 is at a second level (e.g., high level, 10 volts). Similarly, when the second switch S2 is in an off state, the magnitude of the second control signal provided by the switch status detection circuit 132 is at a first level (e.g., low level, 0 volts). When the second switch S2 is in an on state, the magnitude of the second control signal provided by the switch status detection circuit 132 is at a second level (e.g., high level, 10 volts). The plurality of lamps 106A, 106B are off when both the first control signal and the second control signal provided by the switch status detection circuit 132 are at the first level. When the first control signal provided by the switch status detection circuit 132 is at the second level, and the second control signal provided by the switch status detection circuit 132 is at the first level, the lighting system converter circuit 130 operates the plurality of lamps 106A, 106B at a first lighting level (e.g., 30 percent of the rated lamp power). When the first control signal provided by the switch status detection circuit 132 is at the first level and the second control signal provided by the switch status detection circuit 132 is at the second level, the lighting system converter circuit 130 operates the plurality of lamps 106A, 106B at a second lighting level (e.g., 70 percent of the rated lamp power). When the first control signal provided by the switch status detection circuit 132 is at the second level and the second control signal provided by the switch status detection circuit 132 is at the second level, the lighting system converter circuit 130 operates the plurality of lamps 106A, 106B at a third lighting level (e.g., 100 percent of the rated lamp power).

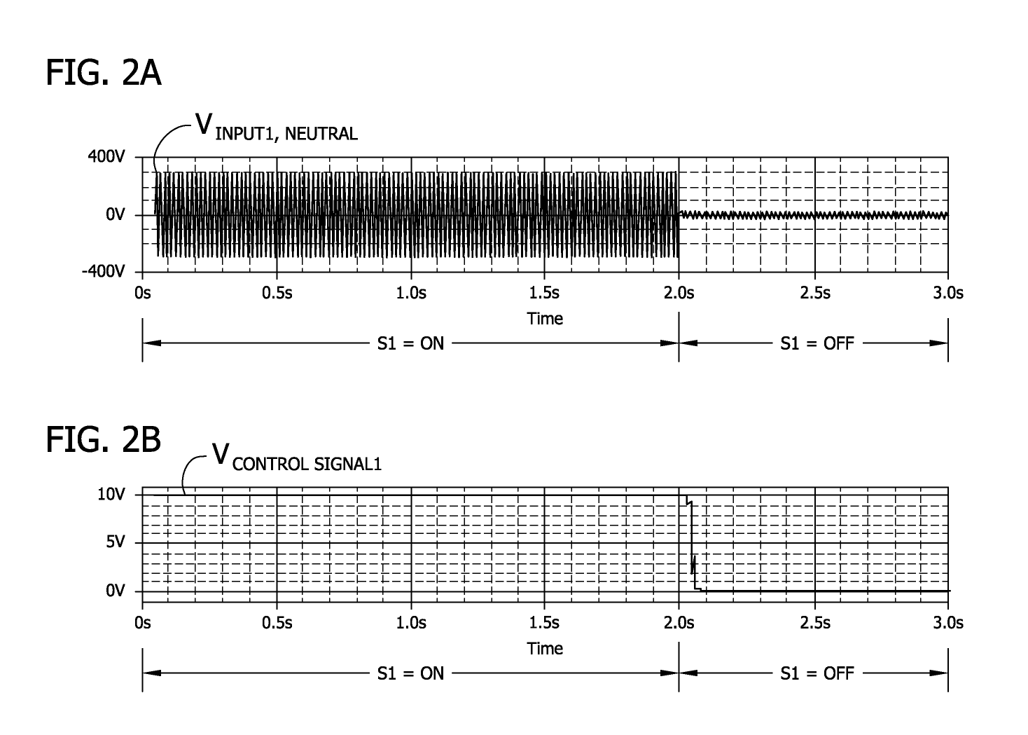

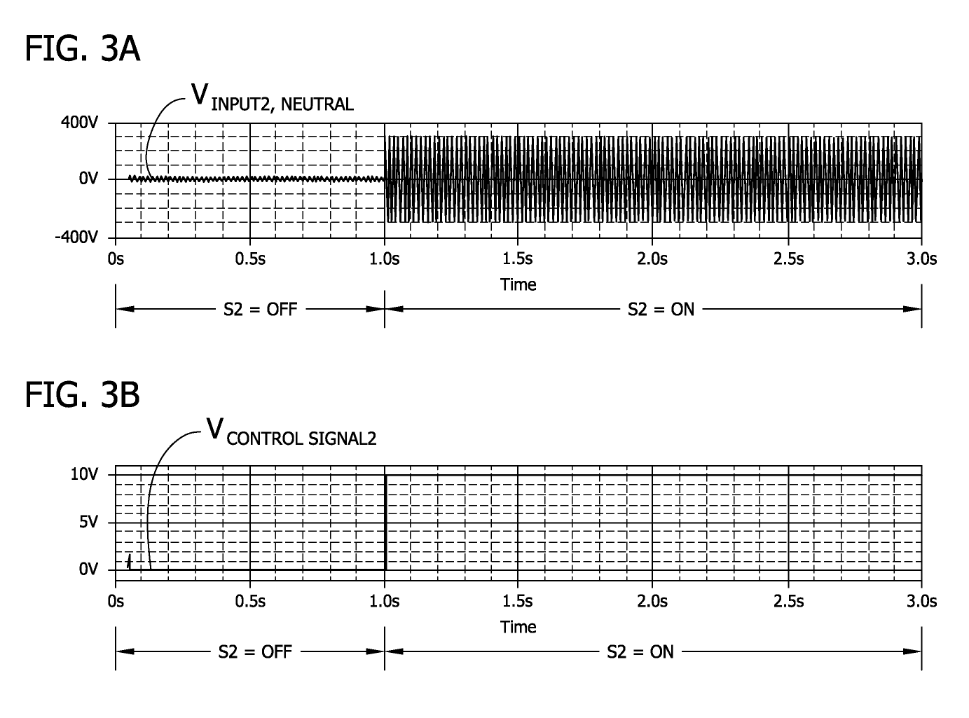

In some embodiments, the switch status detection circuit 132 includes a first input terminal 134 coupled to the first switch S1 via the first inductor L1, and a second input terminal 136 coupled to the second switch via the second inductor L2. A third input terminal 138 is coupled to the neutral input terminal 112 of the AC power supply 102. In operation, the first input terminal 134 receives a first voltage signal from the AC power supply 102, and the second input terminal 136 receives a second voltage signal from the AC power supply 102. FIG. 2A illustrates the first voltage signal V_{INPUT1, NEUTRAL} measured with respect to the neutral terminal 128 during a first time interval while the first switch S1 is conductive (e.g., in an on state, ON) and during a second time interval while the first switch S1 is non-conductive (e.g., in an off state, OFF). Similarly, FIG. 3A illustrates the second voltage signal V_{INPUT2, NEUTRAL} measured with respect to the neutral terminal 128 during a first time interval while the second switch S2 is non-conductive (e.g., in an off state, OFF) and during a second time interval while the second switch S2 is conductive (e.g., in an on state, ON). The switch status detection circuit 132 also includes a first output terminal 142 and a second output terminal 144, both connected to the lighting system converter circuit 130. The switch status detection circuit 132 provides the first control signal, which indicates the status of the first switch S1, to the lighting system converter circuit 130 via the first output terminal 142. The switch status detection circuit 132 provides the second control signal, which indicates the status of the second switch S2, to the lighting system converter circuit 130 via the second output terminal 144. FIG. 2B illustrates the first control signal V_{CONTROL SIGNAL1} that the switch status detection circuit 132 generates at the first output terminal 142 as a function of the first voltage signal V_{INPUT1, NEUTRAL} illustrated in FIG. 2A. FIG. 3B illustrates the second control signal V_{CONTROL SIGNAL2} that the switch status detection circuit 132 generates at the second output terminal 144 as a function of the second voltage signal V_{INPUT2, NEUTRAL} illustrated in FIG. 3A.

A neutral synchronization circuit is connected between the third input terminal 138 and the ground terminal 140 to generate a positive pulsed current signal as a function of the neutral voltage signal. In the switch status detection circuit 132 as shown in FIG. 1, the neutral synchronization circuit comprises a resistor R1, a capacitor C4, and a diode D7. However, it should be noted that other circuit components may be used without departing from the scope of the invention. The resistor R1 is connected to the neutral input terminal 112 via the third EMI inductor L3, and the capacitor C4 is connected in series with the resistor R1. The diode D7 has an anode connected to the ground terminal 140, and a cathode connected to the capacitor C4.

The switch status detection circuit 132 also includes a first detection channel and a second detection channel. The first detection channel is connected to the neutral synchronization circuit, the first input terminal 134, and the first output terminal 142 of the switch status detection circuit 132 to generate the first control signal. The first detection channel comprises bipolar NPN transistors (e.g., model number 2N3904 available from Fairchild Semiconductor Corporation) Q1 and Q4, a capacitor C1, a diode D8, and resistors R2, R4, R6, and R9. However, it should be noted that other circuit components may be used without departing from the scope of the invention. The transistors Q1 and Q4 each have an emitter terminal, a base terminal, and a collector terminal. The base terminal of the transistor Q1 is connected to the neutral synchronization circuit at the cathode of the diode D7 via the resistor R2. The emitter terminal of the transistor Q1 is connected to the first input terminal 134 via the diode D8. In particular, the diode D8 has an anode connected to the emitter terminal of the transistor Q1 and a cathode that is connected to the first input terminal 134. The resistor R4 is connected between the collector and emitter terminals of the transistor Q1. The collector terminal of the transistor Q1 is connected to the ground terminal 140 via the capacitor C1 and is connected to the base terminal of the transistor Q4 via the resistor R6. The base terminal of the transistor Q4 is connected to the ground terminal 140 via the resistor R9. The emitter terminal of the transistor Q4 is also connected to the ground terminal 140. The collector terminal of the transistor Q4 is connected to the first output terminal 142 to provide the first control signal to the lighting system converter circuit 130.

The second detection channel comprises bipolar NPN transistors (e.g., model number 2N3904 available from Fairchild Semiconductor Corporation) Q2 and Q3, a capacitor C2, a diode D9, and resistors R3, R5, R7, and R8. However, it should be noted that other circuit components may be used without departing from the scope of the invention. As shown in FIG. 1, the transistors Q2 and Q3 each have an emitter terminal, a base terminal, and a collector terminal. The base terminal of the transistor Q2 is connected to the neutral synchronization circuit at the cathode of the diode D7 via the resistor R3. The emitter terminal of the transistor Q2 is connected to the second input terminal 136 via the diode D9. In particular, the diode D9 has an anode connected to the emitter terminal of the transistor Q2 and a cathode that is connected to the second input terminal 136. The resistor R5 is connected between the collector and emitter terminals of the transistor Q2. The collector terminal of the transistor Q2 is connected to the ground terminal 140 via the capacitor C2 and is connected to the base terminal of the transistor Q3 via the resistor R7. The base terminal of the transistor Q3 is connected to the ground terminal 140 via the resistor R8. The emitter terminal of the transistor Q3 is also connected to the ground terminal 140. The collector terminal of the transistor Q3 is connected to the second output terminal 144 to provide the second control signal to the lighting system converter circuit 130.

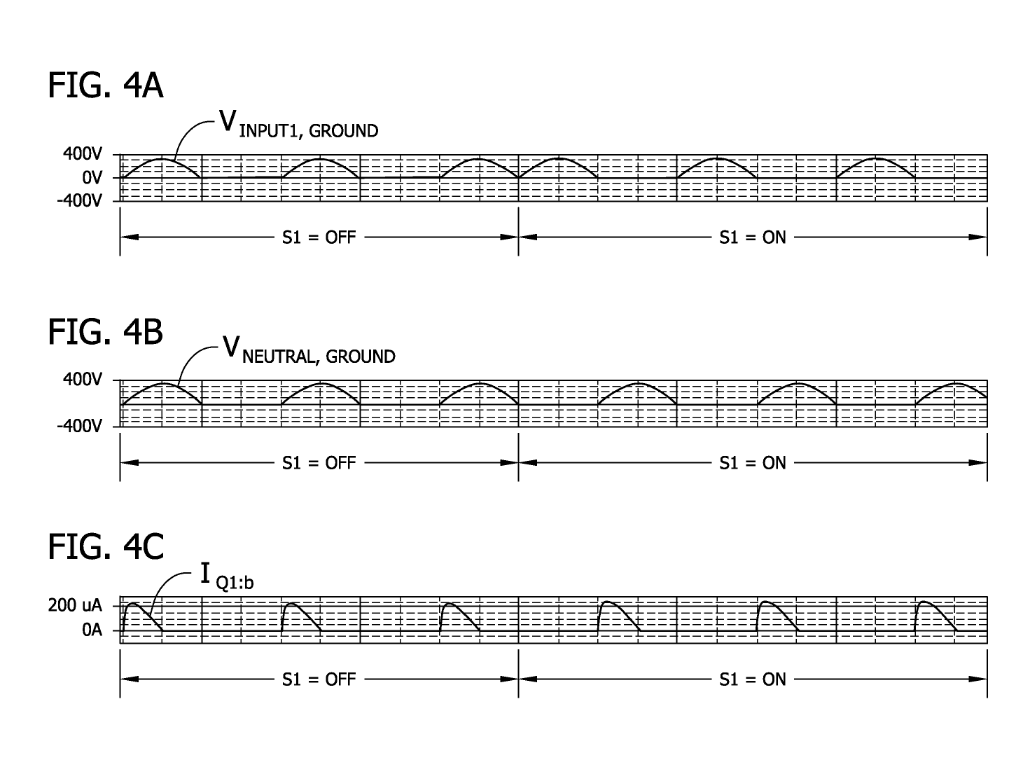

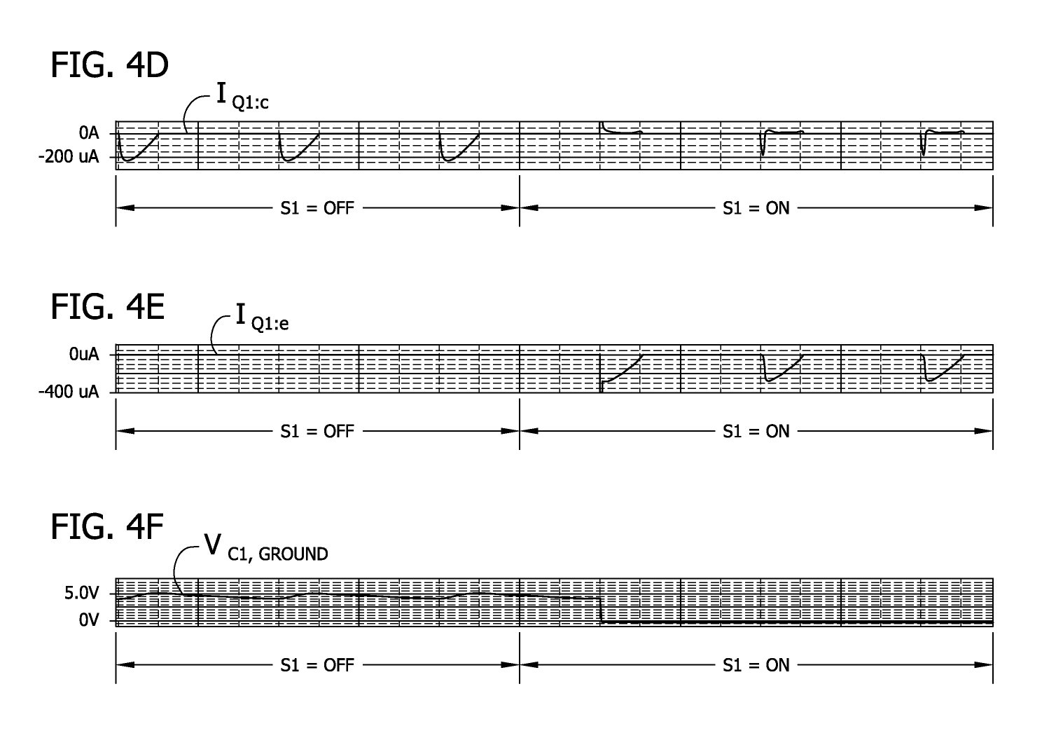

In operation, the first input terminal 134, the second input terminal 136, and the third input terminal 138 each receive a voltage signal relative to ground potential (i.e., the first voltage signal V_{INPUT1, GROUND}, the second voltage signal V_{INPUT2, GROUND}, and the neutral voltage signal V_{NEUTRAL, GROUND}, respectively) generated from an AC voltage signal from the AC power supply 102. The AC voltage signal provided by the AC power supply 102 is rectified to produce the voltage signal, which consists of positive half waves. FIG. 4A illustrates an exemplary waveform of the first voltage signal V_{INPUT1, GROUND} while the first switch 51 is non-conductive (i.e., in an off state, OFF), and while the first switch 51 is conductive (i.e, in an on state, ON). As illustrated, the first voltage signal V_{INPUT1, GROUND} has a first phase when the first switch 51 is non-conductive, and a second phase when the first switch 51 is conductive. The second phase differs from the first phase by, for example but not limited to, one hundred and eighty degrees (i.e., about one hundred and eighty degrees). The first input terminal 134 has a relatively high impedance when the first switch 51 is non-conductive. Accordingly, the potential at the first input terminal 134 is driven by the neutral voltage signal V_{NEUTRAL, GROUND} through the EMI capacitor Cx1 so that the first voltage signal V_{INPUT1, GROUND} and the neutral voltage signal V_{NEUTRAL, GROUND} are in-phase while the first switch Si is non-conductive (i.e., in an off state, OFF).

FIG. 4B illustrates an exemplary waveform of the neutral voltage signal V_{NEUTRAL, GROUND} while the first switch S1 is non-conductive (i.e., in an off state, OFF), and while the first switch S1 is conductive (i.e., in an on state, ON). As illustrated, the neutral voltage signal V_{NEUTRAL,GROUND} is in-phase with the first voltage signal V_{INPUT1, GROUND} while the first switch S1 is non-conductive (i.e., in an off state, OFF). That is, the first voltage signal V_{INPUT1, GROUND} has a first phase. The neutral voltage signal V_{NEUTRAL, GROUND} is one hundred and eighty degrees out of phase with the first voltage signal V_{INPUT1, GROUND} while the first switch S1 is conductive (i.e., in an on state, ON). That is, the first voltage signal V_{INPUT1, GROUND} has a second phase. The neutral synchronization circuit receives the neutral voltage signal V_{NEUTRAL, GROUND} via the third input terminal 138 and produces a positive pulsed current signal I_{Q1:b} as a function thereof. FIG. 4C illustrates an exemplary waveform of the positive pulsed current signal I_{Q1:b} produced by the neutral synchronization circuit. As illustrated, the positive pulsed current signal I_{Q1:b} is substantially in-phase with the neutral voltage signal V_{NEUTRAL, GROUND}. Thus, the positive pulsed current signal I_{Q1:b} is in-phase with the first voltage signal V_{INPUT1, GROUND} while the first switch S1 is non-conductive (i.e., in an off state, OFF), and is one hundred and eighty degrees out of phase with the first voltage signal V_{INPUT1, GROUND} while the first switch S1 is conductive (i.e., in an on state, ON).

The first detection channel receives the positive pulsed current signal I_{Q1:b} from the neutral synchronization circuit and receives the first voltage signal V_{INPUT1, GROUND} via the first input terminal 134. As shown in FIG. 1, the base terminal of the transistor Q1 receives the positive pulsed current signal I_{Q1:b} via the resistor R2. FIGS. 4D and 4E illustrate current signals, I_{Q1:c}, and I_{Q1:e}, respectively, at the collector and emitter terminals, respectively, of the transistor Q1. The first voltage signal V_{INPUT1, GROUND} reverse biases the diode D8 during the positive half wave portions of the first voltage signal cycle. The diode D8 is forward biased during the non-positive (e.g., 0 Volts) portions of the first voltage signal cycle. When reverse biased, the diode D8 prevents (e.g., blocks) the positive pulses in the positive pulsed current signal I_{Q1:b} from flowing through the emitter terminal of the transistor Q1 (e.g., Q1 emitter blocking time interval) so that the positive pulses in the positive pulsed current signal I_{Q1:b} thereby charge the capacitor C1. When forward biased, the diode D8 allows the positive pulses in the positive pulsed current signal I_{Q1:b} to flow through the emitter terminal of the transistor Q1, and thus no charge is stored in the capacitor C1. As such, when the first voltage signal V_{INPUT1, GROUND} and the neutral voltage signal V_{NEUTRAL, GROUND} (i.e., positive pulsed current signal are in-phase (e.g., when the first switch S1 is non-conductive, S1=OFF), the positive pulses in the positive pulsed current signal I_{Q1:b} charge the capacitor C1, which creates a voltage across the capacitor C1. On the other hand, when the first voltage signal V_{INPUT1, GROUND} and the neutral voltage signal V_{NEUTRAL, GROUND} (i.e., positive pulsed current signal are out of phase (e.g., when the first switch S1 is conductive, S1=ON), the positive pulsed current signal I_{Q1:b} flows through the emitter terminal of the transistor Q1; hence the capacitor C1 is not charged and no voltage is produced across the capacitor C1. FIG. 4F illustrates the voltage V_{C1, GROUND} measured with respect to ground across the capacitor C1.

Thus, voltage levels across the capacitor C1 are indicative of the state of the first switch S1. As shown, a positive voltage across the capacitor C1 indicates that the first switch S1 is non-conductive (e.g., in the off state), whereas a substantially zero voltage across the capacitor C1 indicates that the first switch S1 is conductive (e.g., in the on state). In some embodiments, the first detection channel includes an inverter stage to generate, as a function of the voltage levels across the capacitor C1, the first control signal, where the first control signal has logic levels corresponding to the status of the first switch. This information is then provided to the lighting system converter circuit 130. The inverter stage includes resistors R6 and R9, and a transistor Q4. The resistors R6 and R9 define a threshold voltage across the capacitor C1 that causes the transistor Q4 to change states, either from ON to OFF or from OFF to ON. Thus, for example, the inverter stage may be configured to generate the first control signal so that it has a first logic level (e.g., substantially no voltage, 0 Volts) when the voltage across the capacitor C1 is greater than or equal to the threshold voltage, and so that it has a second logic level (e.g., high voltage, 10 Volts) when the voltage across the capacitor C1 is below the threshold voltage. Accordingly, the first control signal has a first logic level (e.g., substantially no voltage, 0 Volts) when the first switch S1 is non-conductive (e.g., OFF state), and has a second logic level (e.g., high voltage, 10 Volts) when the first switch S1 is conductive (e.g., ON state).

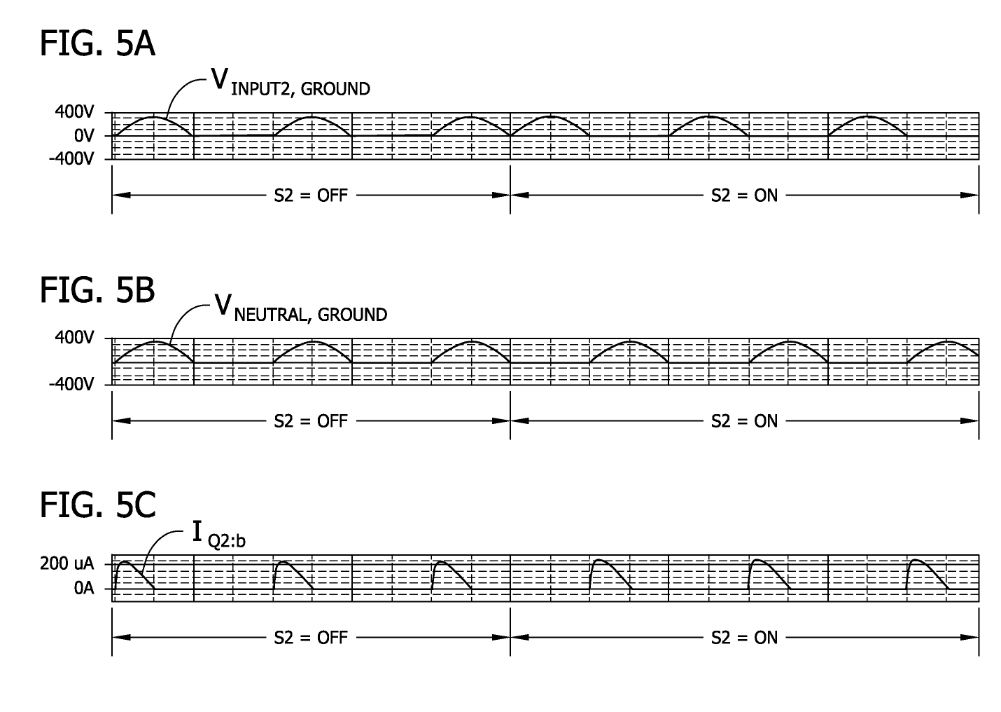

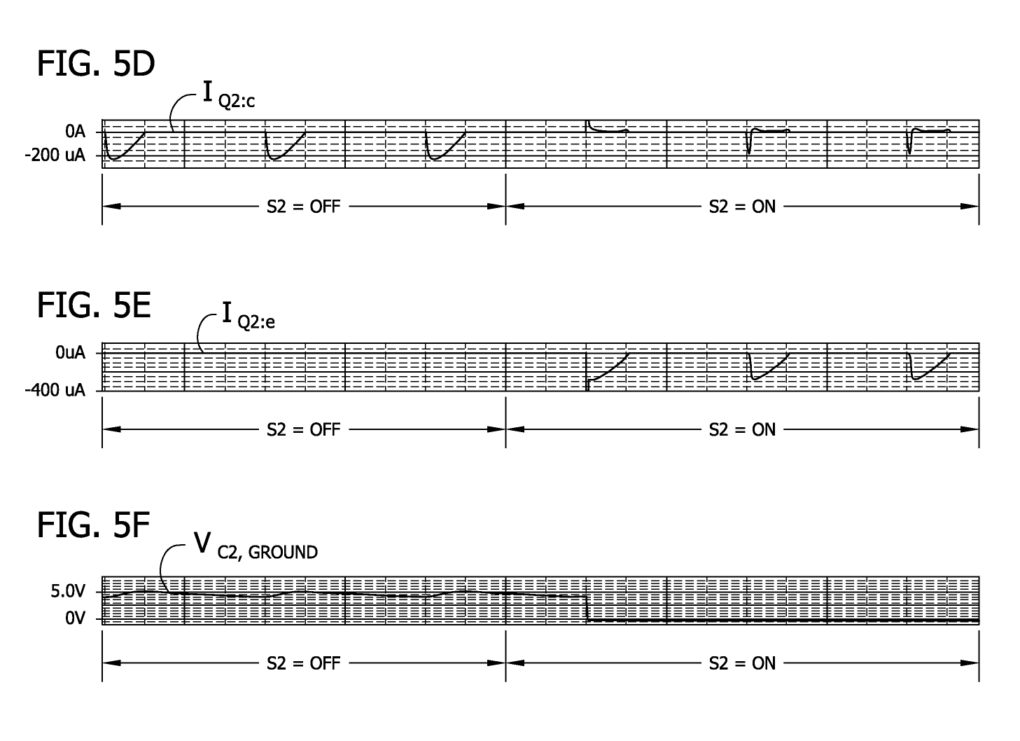

The second detection channel operates similarly to the first detection channel in order to generate the second control signal. In particular, FIG. 5A illustrates an exemplary waveform of the second voltage signal V_{INPUT2, GROUND} while the second switch S2 is non-conductive (S2=OFF), and while the second switch S2 is conductive (S2=ON). As shown, the second voltage signal V_{INPUT2, GROUND} has a first phase when the second switch S2 is non-conductive, and a second phase when the second switch S2 is conductive. The second phase differs from the first phase by one hundred and eighty degrees (i.e., about one hundred and eighty degrees). The second input terminal 136 has a relatively high impedance when the second switch S2 is non-conductive. Accordingly, the potential at the second input terminal 136 is driven by the neutral voltage signal V_{NEUTRAL, GROUND} through the EMI capacitor Cx2, so that the second voltage signal V_{INPUT2, GROUND} and the neutral voltage signal V_{NEUTRAL, GROUND} are in-phase while the second switch S2 is non-conductive (S2=OFF).

FIG. 5B illustrates an exemplary waveform of the neutral voltage signal V_{NEUTRAL, GROUND} while the second switch S2 is non-conductive (S2=OFF), and while the second switch S2 is conductive (S2=ON). As illustrated, the neutral voltage signal V_{NEUTRAL, GROUND} is in-phase with the second voltage signal V_{INPUT2, GROUND} while the second switch S2 is non-conductive (e.g., second voltage signal has first phase), and is one hundred and eighty degrees out of phase with the second voltage signal V_{INPUT2, GROUND} while the second switch S2 is conductive (e.g., second voltage signal has second phase). The neutral synchronization circuit receives the neutral voltage signal V_{NEUTRAL, GROUND} via the third input terminal 138 and produces a positive pulsed current signal I_{Q2:b} as a function thereof. FIG. 5C illustrates an exemplary waveform of the positive pulsed current signal I_{Q2:b} produced by the neutral synchronization circuit. As illustrated, the positive pulsed current signal I_{Q2:b} is substantially in-phase with the neutral voltage signal V_{NEUTRAL, GROUND}. Thus, the positive pulsed current signal I_{Q2:b} is in-phase with the second voltage signal V_{INPUT2, GROUND} while the second switch S2 is non-conductive (e.g., the second voltage signal a has first phase), and is one hundred and eighty degrees out of phase with the second voltage signal V_{INPUT2, GROUND} while the first switch S2 is conductive (e.g., the second voltage signal has a second phase).

The second detection channel receives the positive pulsed current signal I_{Q2:b} from the neutral synchronization circuit and receives the second voltage signal V_{INPUT2, GROUND} via the second input terminal 136. As shown in FIG. 1, the base terminal of the transistor Q2 receives the positive pulsed current signal I_{Q2:b} via the resistor R3. FIGS. 5D and 5E illustrate current signals, I_{Q2:c} and I_{Q2:e}, at the collector and emitter terminals, respectively of the transistor Q2. The second voltage signal V_{INPUT2, GROUND} reverse biases the diode D9 during the positive half wave portions of the second voltage signal cycle. The diode D9 is forward biased during the non-positive (e.g., 0 Volts) portions of the second voltage signal cycle. When reverse biased, the diode D9 prevents (e.g., blocks) the positive pulses in the positive pulsed current signal I_{Q2:b} from flowing through the emitter terminal of the transistor Q2 (e.g., Q2 emitter blocking time interval) so that the positive pulses in the positive pulsed current signal I_{Q2:b} thereby charge the capacitor C2. When forward biased, the diode D9 allows the positive pulses in the positive pulsed current signal I_{Q2:b} to flow through the emitter terminal of the transistor Q2, and thus no charge is stored in the capacitor C2. As such, when the second voltage signal V_{INPUT2, GROUND} and the neutral voltage signal V_{NEUTRAL, GROUND} (i.e., positive pulsed current signal I_{Q2:b}) are in-phase (e.g., when the second switch S2 is non-conductive, S2=OFF), the positive pulses in the positive pulsed current signal I_{Q2:b} charge the capacitor C2, which creates a voltage across the capacitor C2. On the other hand, when the second voltage signal V_{INPUT2, GROUND} and the neutral voltage signal V_{NEUTRAL, GROUND} (i.e., positive pulsed current signal I_{Q2:b}) are out of phase (e.g., when the second switch S2 is conductive, S2=ON), the positive pulsed current signal I_{Q2:b} flows through the emitter terminal of the transistor Q2; hence the capacitor C2 is not charged and no voltage is produced across the capacitor C2. FIG. 5F illustrates the voltage V_{C2, GROUND} measured with respect to ground across the capacitor C2.

Thus, voltage levels across the capacitor C2 are indicative of the state of the second switch S2. As shown, a positive voltage across the capacitor C2 indicates that the second switch S2 is non-conductive (e.g., in the off state), whereas a substantially zero voltage across the capacitor C2 indicates that the second switch S2 is conductive (e.g., in the on state). In some embodiments, the second detection channel includes an inverter stage to generate, as a function of the voltage levels across the capacitor C2, the second control signal, wherein the second control signal has logic levels corresponding to the status of the second switch S2. These are provided to the lighting system converter circuit 130. In FIG. 1, the inverter stage includes resistors R7 and R8, and a transistor Q3. The resistors R7 and R8 define a threshold voltage across the capacitor C2 that causes the transistor Q3 to change states, either from ON to OFF or from OFF to ON. Thus, for example, the inverter stage may be configured to generate the second control signal so that it has a first logic level (e.g., substantially no voltage, 0 Volts) when the voltage across the capacitor C2 is greater than or equal to the threshold voltage, and has a second logic level (e.g., high voltage, 10 Volts) when the voltage across the capacitor C2 is below the threshold voltage. Accordingly, the second control signal has a first logic level (e.g., substantially no voltage, 0 Volts) when the second switch S2 is non-conductive (e.g., OFF state) and has a second logic level (e.g., high voltage, 10 Volts) when the second switch S2 is conductive (e.g., ON state).

The switch status detection circuit 132 provides the first and second control signals to the lighting system converter circuit 130. In particular, the first control signal is provided to the lighting system converter circuit 130 via the first output terminal 142, and the second control signal is provided to the lighting system converter circuit 130 via the second output terminal 144. As described above, the lighting system converter circuit 130 controls a voltage level provided to the plurality of lamps 106A, 106B as a function of the first and second control signals to operate the plurality of lamps 106A, 106B at multiple lighting levels. In some embodiments where the plurality of lamps 106A, 106B are solid state light source-based lamps, the lighting system converter circuit 130 may vary a value of DC voltage applied thereto as a function of the first and second control signals to operate the plurality of solid state light source-based lamps 106A, 106B at multiple lighting levels. In other embodiments, the lighting system converter circuit 130 may vary the frequency of the optional inverter (not shown) in order to vary an output impedance of a resonant tank between the optional inverter output and the plurality of lamps 106A, 106B as a function of the first and second control signals to operate the plurality of lamps 106A, 106B at multiple lighting levels.

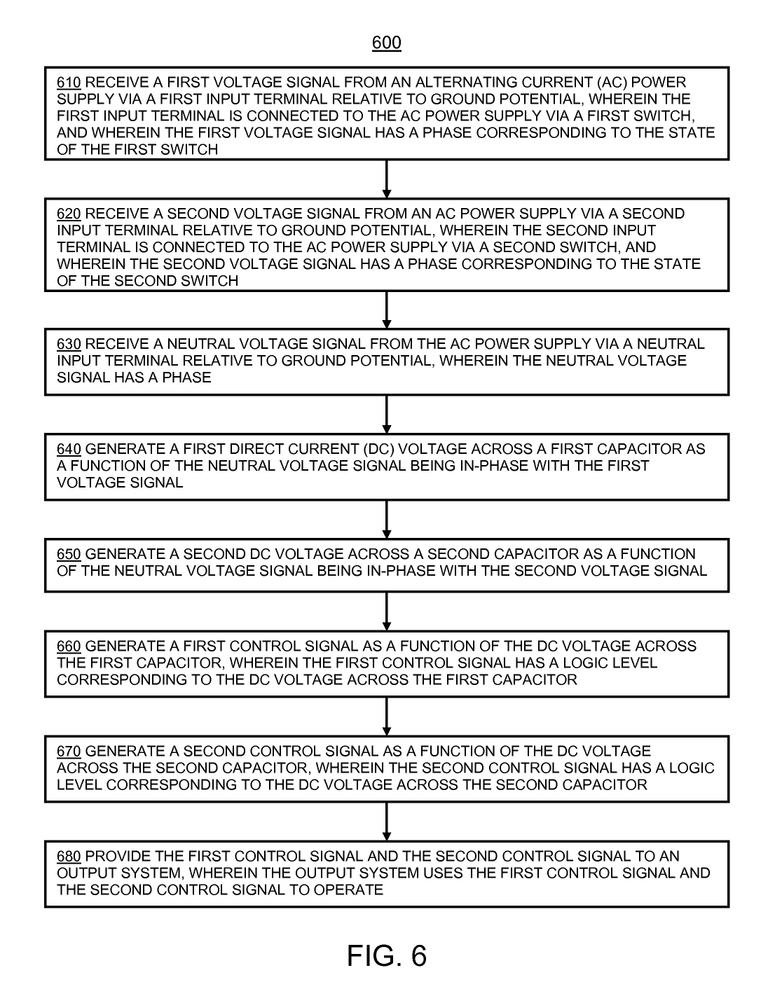

FIGS. 6, 7A-7B, 8A-8B, and 9 are block diagram of methods 600, 700, 800, and 900 that may be performed by the switch status detection circuit 132 shown in FIG. 1. It will be appreciated by those of ordinary skill in the art that unless otherwise indicated herein, the particular sequence of steps described is illustrative only and may be varied without departing from the spirit of the invention. Thus, unless otherwise stated, the steps described below are unordered, meaning that, when possible, the steps may be performed in any convenient or desirable order.

In the method 600 shown in FIG. 6, the switch status detection circuit 132 receives a first voltage signal from an alternating current (AC) power supply 102 via a first input terminal 134 relative to ground potential V_{INPUT1, GROUND}, wherein the first input terminal 134 is connected to the AC power supply 102 via a first switch S1, and wherein the first voltage signal V_{INPUT1, GROUND} has a phase corresponding to the state of the first switch S1, step 610. A second voltage signal is then received from an AC power supply 102 via a second input terminal 136 relative to ground potential V_{INPUT2, GROUND}, wherein the second input terminal 136 is connected to the AC power supply 102 via a second switch S2, and wherein the second voltage signal V_{INPUT2, GROUND} has a phase corresponding to the state of the second switch S2, step 620. The switch status detection circuit 132 then receives a neutral voltage signal from the AC power supply 102 via a neutral input terminal 138 relative to ground potential V_{NEUTRAL, GROUND}, wherein the neutral voltage signal V_{NEUTRAL, GROUND} has a phase, step 630. The switch status detection circuit 132 next generates a first direct current (DC) voltage V_{C1, GROUND} across a first capacitor C1 as a function of the neutral voltage signal V_{NEUTRAL, GROUND} being in-phase with the first voltage signal V_{INPUT1, GROUND}, step 640. Similarly, step 650, the switch status detection circuit 132 generates a second DC voltage V_{C2, GROUND} across a second capacitor C2 as a function of the neutral voltage signal V_{NEUTRAL, GROUND} being in-phase with the second voltage signal V_{INPUT2, GROUND}. The switch status detection circuit 132 then generates a first control signal as a function of the DC voltage V_{C1, GROUND} across the first capacitor C1, wherein the first control signal has a logic level corresponding to the DC voltage V_{C1, GROUND} across the first capacitor C1, step 660. The switch status detection circuit 132 next generates a second control signal as a function of the DC voltage V_{C2, GROUND} across the second capacitor C2, wherein the second control signal has a logic level corresponding to the DC voltage V_{C2, GROUND} across the second capacitor C2, step 670. Finally, the switch status detector circuit 132 provides the first control signal and the second control signal to an output system, wherein the output system uses the first control signal and the second control signal to operate, step 680.

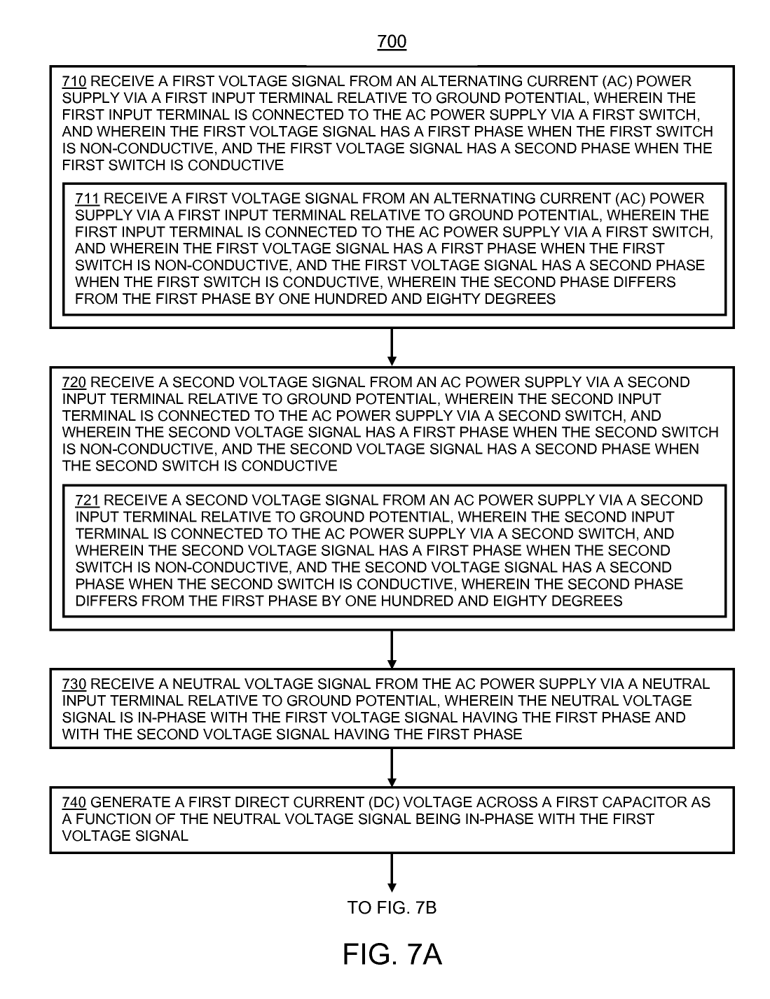

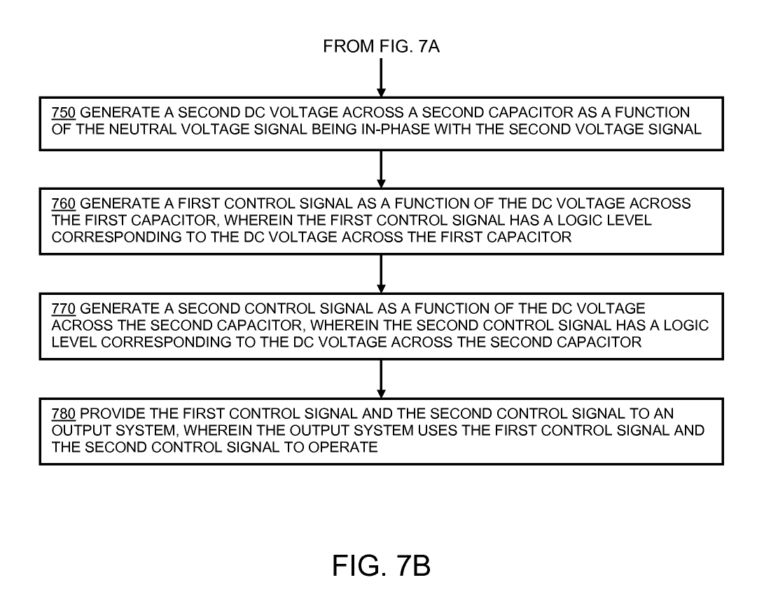

The method 700 shown in FIGS. 7A-7B begins with the switch status detection circuit 132 receiving a first voltage signal from an alternating current (AC) power supply 102 via a first input terminal 134 relative to ground potential V_{INPUT1, GROUND}, wherein the first input terminal 134 is connected to the AC power supply 102 via a first switch 51, and wherein the first voltage signal V_{INPUT1, GROUND} has a first phase when the first switch Si is non-conductive, and the first voltage signal V_{INPUT1, GROUND} has a second phase when the first switch S1 is conductive, step 710. In some embodiments, the second phase differs from the first phase by one hundred and eighty degrees, step 711. The switch status detection circuit 132 then receives a second voltage signal from an AC power supply 102 via a second input terminal 136 relative to ground potential V_{INPUT2, GROUND}, wherein the second input terminal 136 is connected to the AC power supply 102 via a second switch S2, and wherein the second voltage signal V_{INPUT2, GROUND} has a first phase when the second switch S2 is non-conductive, and the second voltage signal V_{INPUT2, GROUND} has a second phase when the second switch S2 is conductive, step 720. In some embodiments, the second phase differs from the first phase by one hundred and eighty degrees, step 721. The switch status detection circuit 132 then receives a neutral voltage signal from the AC power supply 102 via a neutral input terminal 138 relative to ground potential V_{NEUTRAL, GROUND}, wherein the neutral voltage signal V_{NEUTRAL, GROUND} is in-phase with the first voltage signal V_{INPUT1, GROUND} having the first phase and with the second voltage signal V_{INPUT2, GROUND} having the first phase, step 730. The switch status detection circuit 132 next generates a first direct current (DC) voltage V_{C1, GROUND} across a first capacitor C1 as a function of the neutral voltage signal V_{NEUTRAL, GROUND} being in-phase with the first voltage signal V_{INPUT1, GROUND}, step 740. Similarly, step 750, the switch status detection circuit 132 generates a second DC voltage V_{C2, GROUND} across a second capacitor C2 as a function of the neutral voltage signal V_{NEUTRAL, GROUND} being in-phase with the second voltage signal V_{INPUT2, GROUND}. The switch status detection circuit 132 then generates a first control signal as a function of the DC voltage V_{C1, GROUND} across the first capacitor C1, wherein the first control signal has a logic level corresponding to the DC voltage V_{C1, GROUND} across the first capacitor C1, step 760. The switch status detection circuit 132 next generates a second control signal as a function of the DC voltage V_{C2, GROUND} across the second capacitor C2, wherein the second control signal has a logic level corresponding to the DC voltage V_{C2, GROUND} across the second capacitor C2, step 770. Finally, the switch status detector circuit 132 provides the first control signal and the second control signal to an output system, wherein the output system uses the first control signal and the second control signal to operate, step 780.

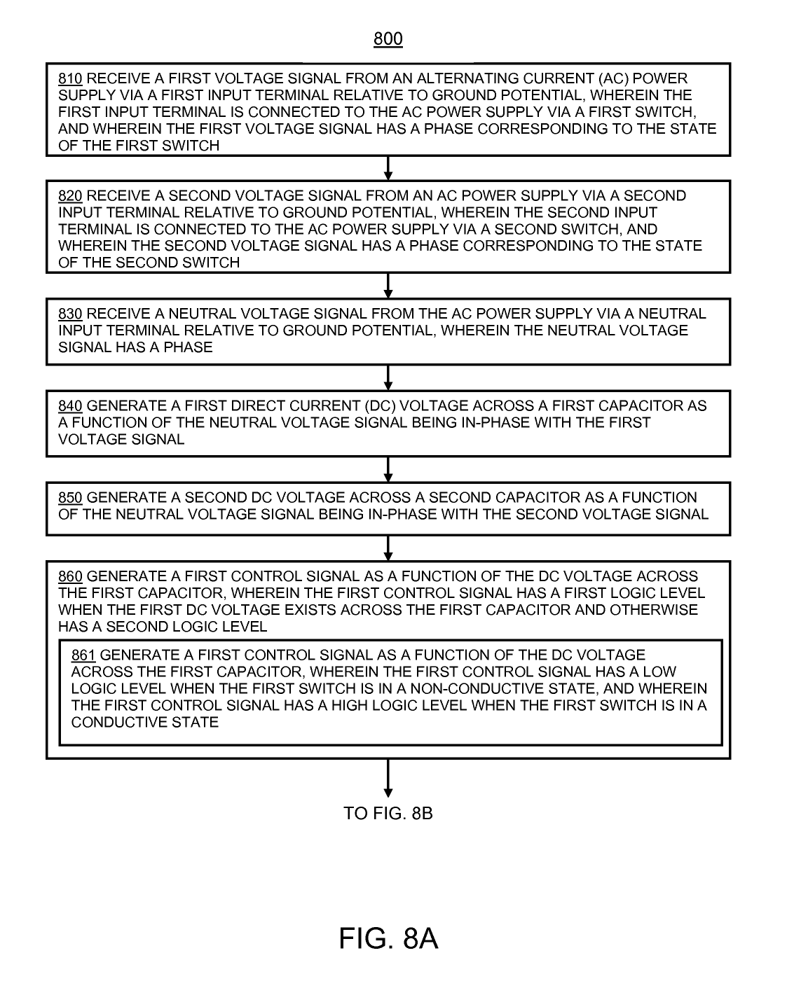

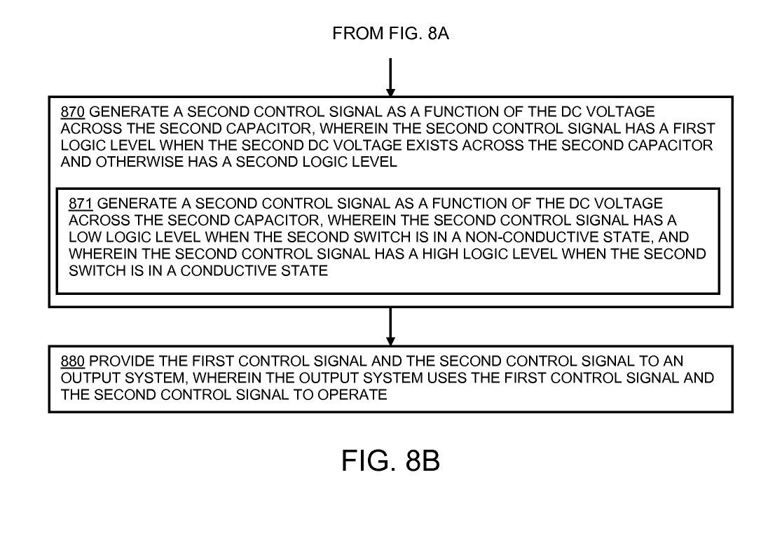

The method 800 shown in FIGS. 8A-8B includes the switch status detection circuit 132 receiving a first voltage signal from an alternating current (AC) power supply 102 via a first input terminal 134 relative to ground potential V_{INPUT1, GROUND}, wherein the first input terminal 134 is connected to the AC power supply 102 via a first switch S1, and wherein the first voltage signal V_{INPUT1, GROUND} has a phase corresponding to the state of the first switch S1, step 810. A second voltage signal is then received from an AC power supply 102 via a second input terminal 136 relative to ground potential V_{INPUT2, GROUND}, wherein the second input terminal 136 is connected to the AC power supply 102 via a second switch S2, and wherein the second voltage signal V_{INPUT2, GROUND} has a phase corresponding to the state of the second switch S2, step 820. The switch status detection circuit 132 then receives a neutral voltage signal from the AC power supply 102 via a neutral input terminal 138 relative to ground potential V_{NEUTRAL, GROUND}, wherein the neutral voltage signal V_{NEUTRAL,GROUND} has a phase, step 830. The switch status detection circuit 132 next generates a first direct current (DC) voltage V_{C1, GROUND} across a first capacitor C1 as a function of the neutral voltage signal V_{NEUTRAL, GROUND} being in-phase with the first voltage signal V_{INPUT1, GROUND}, step 840. Similarly, step 850, the switch status detection circuit 132 generates a second DC voltage V_{C2, GROUND} across a second capacitor C2 as a function of the neutral voltage signal V_{NEUTRAL, GROUND} being in-phase with the second voltage signal V_{INPUT2, GROUND}. The switch status detection circuit 132 then generates a first control signal as a function of the DC voltage V_{C1, GROUND} across the first capacitor C1, wherein the first control signal has a first logic level when the first DC voltage V_{C1, GROUND} exists across the first capacitor C1 and otherwise has a second logic level, step 860. In some embodiments, the first control signal has a low logic level when the first switch 51 is in a non-conductive state, and the first control signal has a high logic level when the first switch 51 is in a conductive state, step 861. The switch status detection circuit 132 next generates a second control signal as a function of the DC voltage V_{C2, GROUND} across the second capacitor C2, wherein the second control signal has a first logic level when the second DC voltage V_{C2, GROUND} exists across the second capacitor C2 and otherwise has a second logic level, step 870. In some embodiments, the second control signal has a low logic level when the second switch S2 is in a non-conductive state, and the second control signal has a high logic level when the second switch S2 is in a conductive state, step 871. Finally, the switch status detector circuit 132 provides the first control signal and the second control signal to an output system, wherein the output system uses the first control signal and the second control signal to operate, step 880.

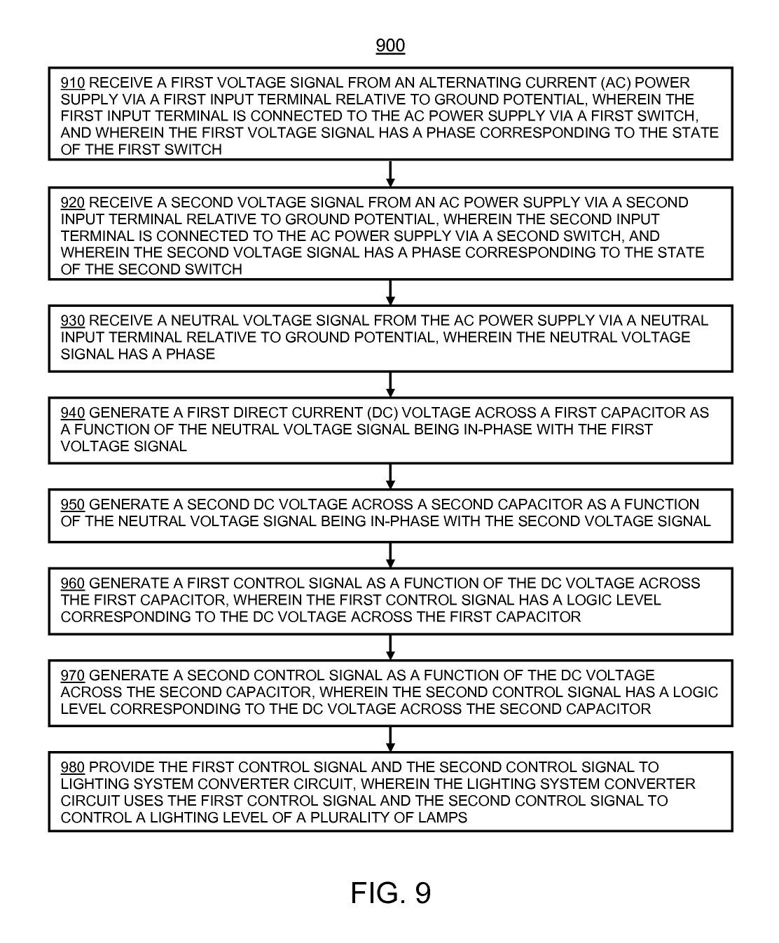

In the method 900 shown in FIG. 9, the switch status detection circuit 132 receives a first voltage signal from an alternating current (AC) power supply 102 via a first input terminal 134 relative to ground potential V_{INPUT1, GROUND}, wherein the first input terminal 134 is connected to the AC power supply 102 via a first switch S1, and wherein the first voltage signal V_{INPUT1, GROUND} has a phase corresponding to the state of the first switch S1, step 910. A second voltage signal is then received from an AC power supply 102 via a second input terminal 136 relative to ground potential V_{INPUT2, GROUND}, wherein the second input terminal 136 is connected to the AC power supply 102 via a second switch S2, and wherein the second voltage signal V_{INPUT2, GROUND} has a phase corresponding to the state of the second switch S2, step 920. The switch status detection circuit 132 then receives a neutral voltage signal from the AC power supply 102 via a neutral input terminal 138 relative to ground potential V_{NEUTRAL, GROUND}, wherein the neutral voltage signal V_{NEUTRAL, GROUND} has a phase, step 930. The switch status detection circuit 132 next generates a first direct current (DC) voltage V_{C1, GROUND} across a first capacitor C1 as a function of the neutral voltage signal V_{NEUTRAL, GROUND} being in-phase with the first voltage signal V_{INPUT1, GROUND}, step 940. Similarly, step 950, the switch status detection circuit 132 generates a second DC voltage V_{C2, GROUND} across a second capacitor C2 as a function of the neutral voltage signal V_{NEUTRAL, GROUND} being in-phase with the second voltage signal V_{INPUT2, GROUND}. The switch status detection circuit 132 then generates a first control signal as a function of the DC voltage V_{C1, GROUND} across the first capacitor C1, wherein the first control signal has a logic level corresponding to the DC voltage V_{C1, GROUND} across the first capacitor C1, step 960. The switch status detection circuit 132 next generates a second control signal as a function of the DC voltage V_{C2, GROUND} across the second capacitor C2, wherein the second control signal has a logic level corresponding to the DC voltage V_{C2, GROUND} across the second capacitor C2, step 970. Finally, the switch status detector circuit 132 provides the first control signal and the second control signal to a lighting system converter circuit 130, wherein the lighting system converter circuit 130 uses the first control signal and the second control signal to control a lighting level of a plurality of lamps 106A, 106B, step 980.

Embodiments of the present invention have been described above in connection with a first and second switch, and a first and second control signal. However, it should be noted that additional switches and corresponding control signals may be produced by the switch status detection circuit 132 without departing from the scope of the invention.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein.

Although the methods and systems have been described relative to a specific embodiment thereof, they are not so limited. Obviously many modifications and variations may become apparent in light of the above teachings. Many additional changes in the details, materials, and arrangement of parts, herein described and illustrated, may be made by those skilled in the art.

What is claimed is:

1. A switch status detection circuit, comprising:
a first input terminal adapted to connect to an AC power supply via a first switch and to receive a first voltage signal with respect to ground potential from the AC power supply;
a second input terminal adapted to connect to the AC power supply via a second switch and to receive a second voltage signal with respect to ground potential from the AC power supply;
a third input terminal adapted to connect to a neutral input terminal of the AC power supply and to receive a neutral voltage signal with respect to ground potential from the AC voltage supply;
a ground terminal adapted to couple to ground potential;
a neutral synchronization circuit connected between the third input terminal and the ground terminal, the neutral synchronization circuit configured to generate a positive pulsed current signal as a function of the neutral voltage signal;
a first capacitor having a first terminal and a second terminal, wherein the first terminal of the first capacitor is coupled to the first input terminal, and wherein the second terminal of the first capacitor is coupled to the ground terminal, and wherein the positive pulsed current signal charges the first capacitor when the first switch is in an off state;
a second capacitor having a first terminal and a second terminal, wherein the first terminal of the second capacitor is coupled to the second input terminal, and wherein the second terminal of the second capacitor is coupled to the ground terminal, and wherein the positive pulsed current signal charges the second capacitor when the second switch is in an off state;
a first output terminal coupled to the first terminal of the first capacitor to provide a first control signal that indicates a state of the first switch as a function of a voltage level across the first capacitor, the first control signal having a first logic level when the first switch is in the off state, the first control signal having a second logic level when the when the first switch is in an on state; and
a second output terminal coupled to the first terminal of the second capacitor to provide a second control signal that indicates a state of the second switch as a function of a voltage level across the second capacitor, the second control signal having a first logic level when the second switch is in the off state, the second control signal having a second logic level when the when the second switch is in an on state.

2. The switch status detection circuit of claim 1, wherein the neutral synchronization circuit comprises:
a resistor connected to the third input terminal;
a neutral synchronization capacitor connected in series with the resistor; and
a diode having an anode connected to the ground terminal, and a cathode connected to the neutral synchronization capacitor.

3. The switch status detection circuit of claim 2, further comprising:
a first transistor having a base terminal, an emitter terminal, and a collector terminal, wherein the base terminal of the first transistor is connected to the neutral synchronization capacitor, the emitter terminal of the first transistor is connected to the first input terminal via a first detection channel diode, and the collector terminal of the first transistor is connected to the emitter terminal of the first transistor via a first detection channel resistor; and
a second transistor having a base terminal, an emitter terminal, and a collector terminal, wherein the base terminal of the second transistor is connected to the neutral synchronization capacitor, the emitter terminal of the second transistor is connected to the second input terminal via a second detection channel diode, and the collector terminal of the second transistor is connected to the emitter terminal of the second transistor via a second detection channel resistor.

4. The switch status detection circuit of claim 2, further comprising:
a first inverter stage to generate the first control signal as a function of the voltage level across the first capacitor; and
a second inverter stage to generate the second control signal as a function of the voltage level across the second capacitor.

5. The switch status detection circuit of claim 1, wherein the first control signal has a low logic level when the first switch is in the off state and the first control signal has a high logic level when the first switch is in the on state, and wherein the second control signal has a low logic level when the second switch is in the off state and the second control signal has a high logic level when the second switch is in the on state.

6. The switch status detection circuit of claim 1, wherein the first output terminal is connected to a lighting system converter circuit to provide the first control signal thereto, and the second output terminal is connected to the lighting system converter circuit to provide the second control signal thereto, wherein the lighting system converter circuit provides voltage to a plurality of lamps as a function of the logic level of the first control signal and the logic level of the second control signal.

7. A method implemented by a switch status detection circuit, comprising:
receiving a first voltage signal from an alternating current (AC) power supply via a first input terminal relative to ground potential, wherein the first input terminal is connected to the AC power supply via a first switch, and wherein the first voltage signal has a phase corresponding to the state of the first switch;
receiving a second voltage signal from an AC power supply via a second input terminal relative to ground potential, wherein the second input terminal is connected to the AC power supply via a second switch, and wherein the second voltage signal has a phase corresponding to the state of the second switch;
receiving a neutral voltage signal from the AC power supply via a neutral input terminal relative to ground potential, wherein the neutral voltage signal has a phase;
generating a first direct current (DC) voltage across a first capacitor as a function of the neutral voltage signal being in-phase with the first voltage signal;
generating a second DC voltage across a second capacitor as a function of the neutral voltage signal being in-phase with the second voltage signal;
generating a first control signal as a function of the DC voltage across the first capacitor, wherein the first control signal has a logic level corresponding to the DC voltage across the first capacitor;
generating a second control signal as a function of the DC voltage across the second capacitor, wherein the second control signal has a logic level corresponding to the DC voltage across the second capacitor; and
providing the first control signal and the second control signal to an output system, wherein the output system uses the first control signal and the second control signal to operate.

8. The method of claim 7, wherein receiving a first voltage signal comprises:
receiving a first voltage signal from an alternating current (AC) power supply via a first input terminal relative to ground potential, wherein the first input terminal is connected to the AC power supply via a first switch, and wherein the first voltage signal has a first phase when the first switch is non-conductive, and the first voltage signal has a second phase when the first switch is conductive.

9. The method of claim 8, wherein receiving a first voltage signal comprises:
receiving a first voltage signal from an alternating current (AC) power supply via a first input terminal relative to ground potential, wherein the first input terminal is connected to the AC power supply via a first switch, and wherein the first voltage signal has a first phase when the first switch is non-conductive, and the first voltage signal has a second phase when the first switch is conductive, wherein the second phase differs from the first phase by one hundred and eighty degrees.

10. The method of claim 8, wherein receiving a second voltage signal comprises:
receiving a second voltage signal from an AC power supply via a second input terminal relative to ground potential, wherein the second input terminal is connected to the AC power supply via a second switch, and wherein the second voltage signal has a first phase when the second switch is non-conductive, and the second voltage signal has a second phase when the second switch is conductive.

11. The method of claim 10, wherein receiving a second voltage signal comprises:
receiving a second voltage signal from an AC power supply via a second input terminal relative to ground potential, wherein the second input terminal is connected to the AC power supply via a second switch, and wherein the second voltage signal has a first phase when the second switch is non-conductive, and the second voltage signal has a second phase when the second switch is conductive, wherein the second phase differs from the first phase by one hundred and eighty degrees.

12. The method of claim 10, wherein receiving a neutral voltage signal comprises:
receiving a neutral voltage signal from the AC power supply via a neutral input terminal relative to ground potential, wherein the neutral voltage signal is in-phase with the first voltage signal having the first phase and with the second voltage signal having the first phase.

13. The method of claim 7, wherein generating a first control signal comprises:
generating a first control signal as a function of the DC voltage across the first capacitor, wherein the first control signal has a first logic level when the first DC voltage exists across the first capacitor and otherwise has a second logic level.

14. The method of claim 13, wherein generating a second control signal comprises:
generating a second control signal as a function of the DC voltage across the second capacitor, wherein the second control signal has a first logic level when the second DC voltage exists across the second capacitor and otherwise has a second logic level.

15. The method of claim 14, wherein generating a first control signal comprises:
generating a first control signal as a function of the DC voltage across the first capacitor, wherein the first control signal has a low logic level when the first switch is in a non-conductive state, and wherein the first control signal has a high logic level when the first switch is in a conductive state;
and wherein generating a second control signal comprises:
generating a second control signal as a function of the DC voltage across the second capacitor, wherein the second control signal has a low logic level when the second switch is in a non-conductive state, and wherein the second control signal has a high logic level when the second switch is in a conductive state.

16. The method of claim 7, wherein providing the first control signal and the second control signal to an output system comprises:
providing the first control signal and the second control signal to a lighting system converter circuit, wherein the lighting system converter circuit uses the first control signal and the second control signal to control a lighting level of a plurality of lamps.

17. A power converter to power a plurality of lamps from an alternating current (AC) power supply, the power converter comprising:
a first switch adapted to selectively connect the power converter to a first high voltage terminal of the AC power supply, the first switch having an on state and an off state;
a second switch adapted to selectively connect the power converter to a second high voltage terminal of the AC power supply, the second switch having an on state and an off state;
a lighting system converter circuit to provide power suitable for energizing at least one lamp in the plurality of lamps; and
a switch status detection circuit comprising:
a first input terminal coupled to the first switch to receive a first voltage signal with respect to ground potential from the AC power supply;
a second input terminal coupled to the second switch to receive a second voltage signal with respect to ground potential from the AC power supply;
a third input terminal coupled to a neutral input terminal of the AC power supply to receive a neutral voltage signal with respect to ground potential from the AC voltage supply;
a ground terminal coupled to ground potential;
a neutral synchronization circuit connected between the third input terminal and the ground terminal, the neutral synchronization circuit configured to generate a positive pulsed current signal as a function of the neutral voltage signal;
a first capacitor having a first terminal and a second terminal, wherein the first terminal of the first capacitor is coupled to the first input terminal of the switch status detection circuit, and wherein the second terminal of the first capacitor is coupled to the ground terminal of the switch status detection circuit, and wherein the positive pulsed current signal charges the first capacitor when the first switch is in the off state;
a second capacitor having a first terminal and a second terminal, wherein the first terminal of the second capacitor is coupled to the second input terminal of the switch status detection circuit, and wherein the second terminal of the second capacitor is coupled to the ground terminal of the switch status detection circuit, and wherein the positive pulsed current signal charges the second capacitor when the second switch is in the off state;
a first output terminal coupled to the first terminal of the first capacitor and to the lighting system converter circuit to provide a first control signal to the lighting system converter circuit, wherein the first control signal indicates the state of the first switch as a function of a voltage level across the first capacitor, the first control signal having a first logic level when the first switch is in the off state, the first control signal having a second logic level when the when the first switch is in the on state; and
a second output terminal coupled to the first terminal of the second capacitor and to the lighting system converter circuit to provide a second control signal to the lighting system converter circuit, wherein the second control signal indicates the state of the second switch as a function of a voltage level across the second capacitor, the second control signal having a first logic level when the second switch is in the off state, the second control signal having a second logic level when the when the second switch is in the on state;
wherein the lighting system converter circuit receives the first control signal via the first output terminal of the switch status detection circuit and receives the second control signal via the second output terminal of the switch status detection circuit, and provides power to the plurality of lamps as a function of the logic level of the first control signal and the logic level of the second control signal.

18. The power converter of claim 17, wherein the neutral synchronization circuit comprises:
a resistor connected to the third input terminal;
a neutral synchronization capacitor connected in series with the resistor; and
a diode having an anode connected to the ground terminal, and a cathode connected to the neutral synchronization capacitor.

19. The power converter of claim 18, further comprising:
a first transistor having a base terminal, an emitter terminal, and a collector terminal, wherein the base terminal of the first transistor is connected to the neutral synchronization capacitor, the emitter terminal of the first transistor is connected to the first input terminal via a first detection channel diode, and the collector terminal of the first transistor is connected to the emitter terminal of the first transistor via a first detection channel resistor; and
a second transistor having a base terminal, an emitter terminal, and a collector terminal, wherein the base terminal of the second transistor is connected to the neutral synchronization capacitor, the emitter terminal of the second transistor is connected to the second input terminal via a second detection channel diode, and the collector terminal of the second transistor is connected to the emitter terminal of the second transistor via a second detection channel resistor.

20. The power converter of claim 18, further comprising:
a first inverter stage to generate the first control signal as a function of the voltage level across the first capacitor; and
a second inverter stage to generate the second control signal as a function of the voltage level across the second capacitor.
